(19) United States
(12) Patent Application Publication
(10) Pub. No.: US 2010/0085068 A1
(43) Pub. Date: Apr. 8, 2010

(54) SENSOR DEVICE FOR DETECTING ELECTRICAL PROPERTIES OF A FLUID

(76) Inventors: Udo KAESS, Stuttgart (DE); Gustav Klett, Moessingen (DE); Markus Niemann, Beckingen (DE)

Correspondence Address: KENYON & KENYON LLP, ONE BROADWAY, NEW YORK, NY, 10004, US

(21) Appl. No.: 12/574,205

(22) Filed: Oct. 6, 2009

(30) Foreign Application Priority Data
Oct. 8, 2008 (DE) 102008042673.3

(51) Int. Cl. G01R 27/08

(52) U.S. Cl. 324/722

(57) ABSTRACT

The sensor device for detecting electrical properties of a fluid under high pressure has: a pressure-tight housing, whose cavity is connectable to a high pressure line via an opening, a sensor for electrical properties, which is situated in the cavity, glass feedthroughs, which electrically connect the contacts on an external surface of the housing to the sensor.

### FIELD OF THE INVENTION

The present invention relates to a sensor device for detecting electrical properties of a fluid, in particular a fluid under high pressure.

### BACKGROUND INFORMATION

Fuels for motor vehicles may be mixed, e.g., diesel and ethanol. For optimum combustion and performance output, the composition of the fuel mixture is to be determined.

Electrical properties, e.g., the dielectric constant and the specific conductance, are characteristic for the individual fuels. By determining the electrical properties, a mixing ratio of the fuels may subsequently be inferred.

Sensors for detecting the electrical properties are placed in a storage container, e.g., a tank. The fuels may partly segregate, so that a fuel mixture injected into combustion chambers is different from the fuel mixture present at the sensor.

### SUMMARY OF THE INVENTION

The sensor device according to the present invention may be installed in an injection line of a fuel injector. The direct proximity of the sensor to the fuel injector may ensure that the composition of the injected fuel coincides with that of the tested fuel.

The sensor device according to the present invention for detecting electrical properties of a fluid has: a pressure-tight housing, whose cavity is connectable to a high pressure line via an opening, a sensor for electrical properties, which is situated in the cavity, and glass feedthroughs, which electrically connect the contacts on an external surface of the housing to the sensor.

The glass feedthroughs make it possible to install the sensor in areas in which the fluid is under high pressure. The glass feedthroughs may electrically contact interior areas of the sensor and are tight at the same time, so that no fuel may escape.

### BRIEF DESCRIPTION OF THE DRAWINGS

FIG. 1 shows a sensor in cross section.

FIG. 2 shows the sensor in another cross section.

### DETAILED DESCRIPTION

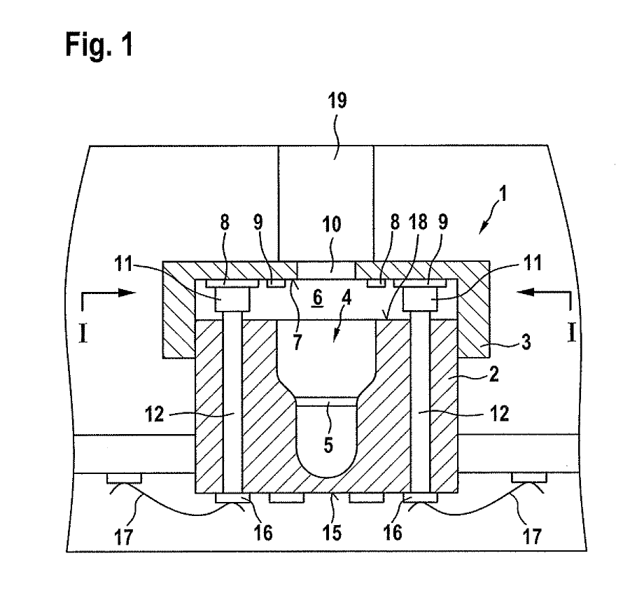

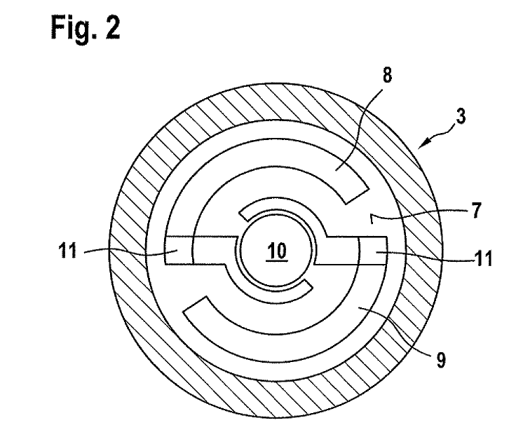

As an example, FIG. 1 shows a sensor 1 in cross section. FIG. 2 shows a section in plane I-I.

A housing of sensor 1 is made up of two half-shells 2, 3.

First half-shell 2 has a recess 4 in which a high pressure sensor 5 is situated. High pressure sensor 5 may have a piezoactive element, for example.

Second half-shell 3 may, as illustrated, enclose first half-shell 2. Both half-shells 2, 3 may have a form-locked design so that a pressure-tight cavity 6 is defined by both half-shells 2, 3. A material connection of the two half-shells 2, 3 may be achieved by welding.

An opening 10 is provided in second half-shell 3 via which a fluid may flow into cavity 6 and recess 4. The fluid may be under high pressure of more than 100 bar or even more than 1,000 bar. Sensor 1 is particularly suitable for feed lines 19 of a fuel injection system. Sensor 1 is situated in the injection system downstream from the pressure-increasing elements, e.g., pumps.

Electrical printed conductors 8, 9 are applied to an interior surface 7, i.e., in cavity 6, of second half-shell 3. FIG. 2 shows printed conductors 8, 9 as circular elements. As an alternative, the printed conductors may be designed as intermeshing comb-like structures. The at least two printed conductors 8, 9 are electrically insulated from one another. The system may be used for determining the electrical properties or for determining the specific electrical conductance of the fluid in cavity 6.

An electrical connection of printed conductors 8, 9 takes place via contacts 11.

Outside contacts 16 are situated on an external surface 15 of first half-shell 2 facing away from second half-shell 3. Outside contacts 16 are used for connecting sensor device 1, e.g., via external bond wires 17, to establish a connection to an analyzer device of the sensor signals.

Glass feedthroughs 12 having an electrical core are situated in a wall 13 of first half-shell 2. in the illustrated variant, glass feedthroughs 12 extend over the entire dimension of first half-shell 2 from external surface 15 facing away from second half-shall 3 up to surface 18 facing second half-shell 3. Glass feedthroughs 12 are embedded over their entire length in the wall of first half-shell 2. Glass feedthroughs 12 may have a length which is at least five times greater than their diameter. Glass feedthroughs 12 or their cores are electrically connected to outside contacts 16.

An electrical connection between glass feedthroughs 12 or their core and contacts 11 of printed conductors 8, 9 is established via a pressed connection. For this purpose, contacts 11 of printed conductors 8, 9 may have conductive elevations. The conductive elevations may have an elastic design.

In addition to the sensor for electrical properties, a temperature sensor may be situated in the cavity. The temperature sensor detects the ambient temperature. The temperature sensor may be contacted via additional glass feedthroughs. An analyzer device may analyze the electrical properties, taking into account their temperature dependency, with the aid of the measured prevailing temperature.

What is claimed is:

1. A sensor device for detecting electrical properties of a fluid, comprising:
a pressure-tight housing having a cavity that is connectable to a high pressure line via an opening;
a sensor for electrical properties which is situated in the cavity; and
glass feedthroughs which electrically connect contacts on an external surface of the housing to the sensor.

2. The sensor device according to claim 1, wherein the fluid is under high pressure.

3. The sensor device according to claim 1, wherein a high pressure sensor is situated in the cavity.

4. The sensor device according to claim 1, wherein the sensor for electrical properties is formed by exposed printed conductors applied to an interior wall of the cavity for detecting at least one of (a) dielectric properties and (b) a conductivity of the fluid.

5. The sensor device according to claim 1, wherein a length of the glass feedthroughs is at least five times greater than a diameter of the glass feedthroughs.

6. The sensor device according to claim 1, wherein the housing is formed by a first shell and a second shell, the sensor for electrical properties being situated on an inside of the second shell and the glass feedthroughs passing through the first shell.

7. The sensor device according to claim 6, wherein contact surfaces of the sensor for electrical properties are pressed onto the glass feedthroughs.

8. The sensor device according to claim 6, wherein the two shells have a form-locked design.

9. The sensor device according to claim 6, wherein the two shells are welded together.
